(19) United States
(12) Patent Application Publication
(10) Pub. No.: US 2008/0142851 A1
(43) Pub. Date: Jun. 19, 2008

(54) CHARGE TRANSFER DEVICE AND SOLID STATE IMAGER DEVICE

(75) Inventors: Shogo Numaguchi, Fukuoka (JP); Kouichi Tanigawa, Kagoshima (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION, Tokyo (JP)

(21) Appl. No.: 11/755,168

(22) Filed: May 30, 2007

(30) Foreign Application Priority Data
Jun. 6, 2006 (JP) P2006-157533

(51) Int. Cl. H01L 27/148

(52) U.S. Cl. 257/231; 257/249; 257/E27.15

(57) ABSTRACT

A charge transfer device includes a charge transfer unit transferring signal charges, and an electric charge-voltage conversion unit detecting signal charges transferred from a last stage of the charge transfer unit via an output gate unit. An electrode in a last stage of the charge transfer unit is divided into first and second electrodes. A predetermined fixed potential is applied to the first electrode disposed on a side of the electric charge-voltage conversion unit. A transfer clock is applied to the second electrode disposed on a side opposite to the charge transfer unit.

### CROSS REFERENCES TO RELATED APPLICATIONS

The present invention contains subject matter related to Japanese Patent Application JP 2006-157533 filed in the Japanese Patent Office on Jun. 6, 2006, the entire contents of which being incorporated herein by reference.

### BACKGROUND OF THE INVENTION

1. Field of the Invention

The present invention relates to a charge transfer device and a solid state imager device. More particularly, the present invention relates to a charge transfer device suitable particularly for use as a horizontal transfer register of a CCD area sensor, a transfer register of a CCD linear sensor and a transfer register of a CCD delay element, and to a solid state imager device using the charge transfer device of this kind.

2. Description of Related Art

FIG. 6 is a schematic plan view for explaining a charge coupled device (CCD) of a solid state imager device of related art, and FIG. 7A is a schematic cross sectional view for explaining the final output stage (corresponding to an area indicated by a symbol “a” in FIG. 6) of a horizontal transfer register of the CCD solid state imager device of related art.

The CCD solid state imager device of related art is constituted of: a plurality of photosensors 101 disposed in a matrix shape in a silicon substrate 100; read gates 102 formed adjacent to the photosensors to read signal charges received in the photosensors; vertical transfer registers 103 disposed adjacent to the read gates to transfer signal charges read by the read gates in a vertical direction; a horizontal transfer register 104 for transferring signal charges transferred from the vertical transfer resisters in a horizontal direction; and channel stop regions 105 disposed at the side of the photosensors opposite to the read gates to suppress color mixture (for example, refer to Japanese Patent Application Publication No. H 10-144907).

Signal charges transferred to the horizontal transfer register are transferred in an output direction by applying transfer clocks to transfer electrodes (H1, H2, LH) on the horizontal transfer register. Specifically, a transfer clock indicated by a symbol Hφ1 in FIG. 8 is applied to a transfer electrode indicated by a symbol H1 in FIG. 7A, a transfer clock indicated by a symbol Hφ2 in FIG. 8 is applied to a transfer electrode indicated by a symbol H2 in FIG. 7A, and a transfer clock indicated by a symbol LHφ in FIG. 8 is applied to a transfer electrode (hereinafter called “LH electrode”) indicated by a symbol LD in FIG. 7A (generally, an amplitude of Hφ1 and an amplitude of Hφ2 are about 3 to 5 V, Hφ1 and Hφ2 have opposite phases, and Hφ1 and LHφ are the same transfer clock). With these transfer clocks, the potentials of the horizontal transfer register are raised and lowered so that signal charges are transferred in the output direction (in FIG. 7A, a direction from right to left).

Signal charges transferred in the horizontal transfer register reach a floating diffusion (FD) with involvement of a transfer electrode HOG (hereinafter called “HOG” electrode”) at the last stage of the horizontal transfer resister. The signal charges transferred to FD are converted into a voltage corresponding to the charge amount by an output circuit, and thereafter discharged into a reset drain RD by applying a reset gate voltage indicated by a symbol RGφ in FIG. 8 to a reset gate RG.

This series of operations is executed to obtain an output signal, such as indicated by a symbol X in FIG. 8, of the solid state imager device.

In the CCD solid state imager device of related art, a voltage HOGφ applied to the HOG electrode is a fixed voltage (e.g., HOGφ=0 V) so as to reduce coupling while the horizontal transfer register is driven by clocks. The coupling means that an output waveform varies with capacitive coupling due to parasitic capacitance between the HOG electrode and a floating region of the output circuit.

Since the fixed voltage is applied to the HOG electrode as described above, the potential under the LH electrode moves up and down because LHφ is applied to the LH electrode, although the potential under the HOG electrode hardly varies. A maximum signal amount (D range) capable of being accumulated under the LH electrode (in a region indicated by a symbol b in FIG. 7B) is defined by the potential under the HOG electrode and the potential under the LH electrode in the state that LHφ takes a high level (hereinafter called “H level”). As the LH electrode changes its state from the H level state to a low level (hereinafter called “L level”) state, a transfer electric field is formed in a direction from the LH electrode to the HOG electrode. Therefore, signal charges, which is accumulated under the LH electrode and exceeds the potential under the HOG electrode, are transferred to FD.

It is needless to say that the larger the D range, the better, and the higher the transfer electric field (transfer indicated by a symbol c in FIG. 7B), the better.

If the potential under the HOG electrode is made deeper in order to improve transfer from the LH electrode to the HOG electrode, a transfer electric field from the LH electrode to the HOG electrode becomes high and transfer of signal charges can be improved, as shown in FIG. 9A. However, the D range is reduced. There has recently appeared a photographing mode in which signal charges of a plurality of pixels are added. The more the number of addition pixels is increased, the more a signal charge amount to be processed increases. There is therefore a tendency that the D range becomes insufficient.

As the D range is reduced and a high luminance object is photographed, there occurs a case in which all of signal charges photoelectrically converted in the photosensor and transferred via the vertical and horizontal transfer registers are not accumulated under the LH electrode and a fraction of the signal charges rides high above the potential under the HOG electrode and is leaked to FD. As signal charges leak to FD, the potential in a P phase of an output signal (in a region indicated by a symbol P of an output signal indicated by a symbol X in FIG. 8) lowers and a potential difference becomes small between the P phase and a D phase (a region indicated by a symbol D of the output signal indicated by the symbol X in FIG. 8). There may arise therefore a demerit that a low luminance area appears in a high luminance object.

On the other hand, if the potential under the HOG electrode is made shallower in order to increase the D range, although the D range defined by the potential under the LH electrode and the potential under the HOG electrode increases as shown in FIG. 9B, a transfer electric field from the LH electrode to HOG electrode becomes low.

As the transfer electric field from the LH electrode to HOG electrode becomes low, there may arise a case in which signal charges are not completely transferred to FD, and a fraction of the signal charges is left under the HOG electrode and mixed with signal charges transferred immediately thereafter. There may arise therefore a demerit that a sensitivity ratio in a low luminance area is unbalanced.

### SUMMARY OF THE INVENTION

As described above, there is a trade-off between the improvement on transfer from the LH electrode to HOG electrode and the improvement on the D range. Although it is very difficult to make both compatible, it has been strongly desired to improve the D range while transfer from the LH electrode to HOG electrode is improved.

As shown in FIG. 10, techniques have been proposed in which the terminal to which Hφ2 is applied and a ground potential are connected via resistors and a transfer clock generated by resistor division is applied to the HOG electrode as HOGφ (for example, Japanese Patent Application Publication No. H08-255896).

If an amplitude of a transfer clock to be applied to the HOG electrode is small, there occurs no problem. However, if the amplitude of the transfer clock is large, the potential in FD is changed, resulting in disturbance of an output signal waveform of the solid state imager device.

The present invention has been made in view of the above-described points. It is desirable to provide a charge transfer device and a solid state imager device capable of improving a D range while improving the transfer from an LH electrode to an HOG electrode.

According to an embodiment of the present invention, there is provided a charge transfer device including: a charge transfer unit transferring signal charges; and an electric charge-voltage conversion unit detecting signal charges transferred from a last stage of the charge transfer unit via an output gate unit, wherein an electrode in a last stage of the charge transfer unit is divided into first and second electrodes, a predetermined fixed potential is applied to the first electrode disposed on a side of the electric charge-voltage conversion unit, and a transfer clock is applied to the second electrode disposed on a side opposite to the charge transfer unit.

According to another embodiment of the present invention, there is provided a solid state imager device including: an imager unit; a charge transfer unit transferring signal charges transferred from the imager unit; and an electric charge-voltage conversion unit detecting signal charges transferred from a last stage of the charge transfer unit via an output gate unit, wherein an electrode for applying a voltage to the output gate unit is divided into first and second electrodes, a predetermined fixed potential is applied to the first electrode disposed on a side of the electric charge-voltage conversion unit, and a transfer clock is applied to the second electrode disposed on a side opposite to the charge transfer unit.

Since the predetermined fixed potential is applied to the first electrode, coupling can be suppressed while the charge transfer unit is driven. Further, since the transfer clock is applied to the second electrode, transfer of signal charges can be improved and the D range can also be increased.

The charge transfer device and solid state imager device of the present invention described above can improve transfer from the LH electrode to HOG electrode and also improve the D range.

### BRIEF DESCRIPTION OF THE DRAWINGS

FIG. 1 is a schematic plan view for explaining a CCD solid state imager device as an example of a solid state imager device adopting the present invention;

FIG. 2 is a schematic cross sectional view for explaining the final output stage of a horizontal transfer register of the CCD solid state imager device as an example of a solid state imager device adopting the present invention;

FIG. 3A shows examples of transfer clocks and FIG. 3B is a schematic diagram for explaining accumulation and transfer of signal charges;

FIG. 4 is a schematic diagram for explaining a modification of the CCD solid state imager device as an example of a solid state imager device adopting the present invention;

FIG. 5A shows examples of transfer clocks and FIG. 5B is a schematic diagram for explaining accumulation and transfer of signal charges;

FIG. 6 is a schematic plan view for explaining a CCD solid state imager device of related art;

FIG. 7A is a schematic cross sectional view for explaining the final output stage of a horizontal transfer register of a CCD solid state imager device of related art, and

FIG. 7B is a schematic diagram for explaining accumulation and transfer of signal charges;

FIG. 8 is a schematic diagram for explaining each transfer clock;

FIGS. 9A and 9B are schematic diagrams for explaining a D range and transfer from an LH electrode to an HOG electrode; and

FIG. 10 is a schematic diagram for explaining a CCD solid state imager device with a transfer clock being applied to the HOG electrode.

### DETAILED DESCRIPTION OF EMBODIMENTS

With reference to the accompanying drawings, description will now be made on the embodiments of the present invention to help understood the present invention.

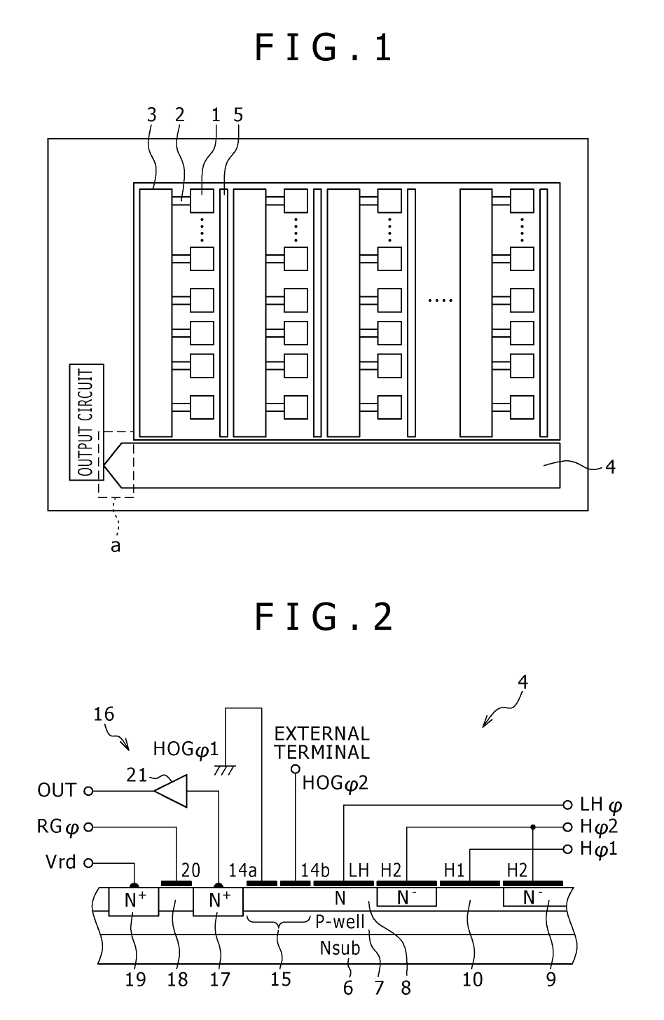

FIG. 1 is a schematic plan view for explaining a CCD solid state imager device as an example of a solid state imager device adopting the present invention, and FIG. 2 is a schematic cross sectional view for explaining the final output stage (region indicated by a symbol a in FIG. 1) of a horizontal transfer register of the CCD solid state imager device as an example of a solid state imager device adopting the present invention.

Similar to the CCD solid state imager device of related art described earlier, the CCD solid state imager device shown in the drawings includes: a plurality of photosensors 1 arrayed in a matrix form in a silicon substrate; read gates 2 formed adjacent to the photosensors to read signal charges received in the photosensors; vertical transfer registers 3 disposed adjacent to the read gates to transfer signal charges read by the read gates in a vertical direction; a horizontal transfer register 4 for transferring signal charges transferred from the vertical transfer resisters in a horizontal direction; and channel stop regions 5 disposed at the side of the photosensors opposite to the read gates to suppress color mixture.

In the horizontal transfer register 4, an N-type channel 8 is formed in a P-type well 7 formed in a surface layer of an N-type semiconductor substrate 6. N⁻-type transfer (TR) regions 9 are formed in a surface layer of the N-type channel at a constant pitch in a right and left direction as viewed in FIG. 2. Channel regions between adjacent transfer regions 9 and 9 constitute storage (ST) regions 10. An electrode H1 made of polysilicon of a first layer is formed above the storage region, and an electrode H2 made of polysilicon of a second layer is formed above the transfer region, respectively via an insulating film (not shown). Two-phase transfer clocks Hφ1 and Hφ2 are applied alternately in the order of electrodes H1 and H2 to each pair of adjacent electrodes H1 and H2 to constitute a two-phase driven horizontal transfer register.

In this horizontal transfer register, a second electrode 14b made of polysilicon of the second layer is formed adjacent to an electrode LH at the last stage, and a first electrode 14a made of polysilicon of the second layer is formed adjacent to the second electrode. The first and second electrodes together with the underlying channel region constitute an output gate unit 15. The first electrode is electrically connected to a ground (earth) which is a reference potential point, and the second electrode is electrically connected to an external terminal.

Signal charges transferred in the horizontal transfer register are output to an electric charge-voltage conversion unit 16 via the output gate unit 15. The electric charge-voltage conversion unit has a floating diffusion amplifier structure including, for example, an N⁺-type floating diffusion (FD) 17 formed adjacent to the output unit, an N⁺-type reset drain (RD) 19 formed at the side of FD via a channel region 18, and a reset gate (RG) 20 formed on the channel region 18 with having an insulating film (not shown) in between. In this electric charge-voltage conversion unit, a constant reset voltage Vrd is applied to the reset drain and a reset gate pulse RGφ is applied to the reset gate. Signal charges injected into the floating diffusion are converted into a voltage by a buffer 21, and thereafter discharged to outside.

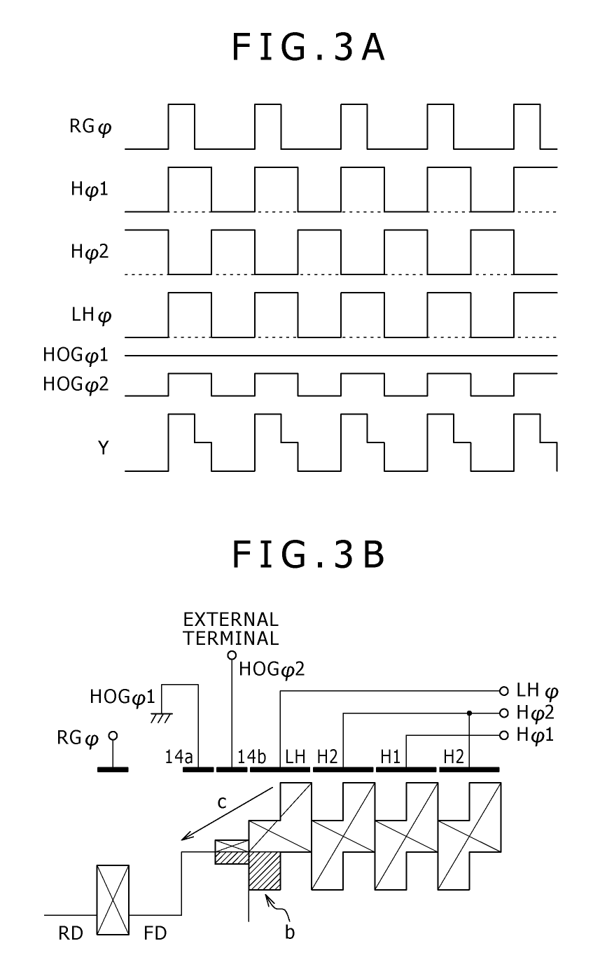

In the CCD solid state imager device constructed as above, a transfer clock indicated by a symbol Hφ1 in FIG. 3A is applied to the electrode H1, a transfer clock indicated by a symbol Hφ2 in FIG. 3A is applied to the electrode H2, a transfer clock indicated by a symbol LHφ in FIG. 3A is applied to the electrode LH at the last stage, a reset gate pulse indicated by a symbol RGφ in FIG. 3A is applied to the reset gate RG, a ground potential indicated by a symbol HOGφ1 in FIG. 3A is applied to the first electrode, and a transfer clock indicated by a symbol HOGφ2 in FIG. 3A is applied to the second electrode, to obtain an output signal of the CCD solid state imager device as indicated by a symbol Y in FIG. 3A. The transfer clock applied to the first electrode is synchronous or substantially synchronous with the transfer clocks applied to the electrodes H1 and LH, and has an amplitude lower than that of the transfer clocks applied to the electrodes H1 and LH.

In the CCD solid state imager device of the present embodiment, as a transfer clock of the H level is applied to the second electrode, signal charges can be accumulated also under the second electrode, whereby the D range can be increased (refer to FIG. 3B). When a transfer clock of the L level is applied to the second electrode, transfer electric fields under the electrode LH, second electrode and first electrode can be shaped to a linear form, thereby enabling smooth transfer from the electrode LH to second electrode and from the second electrode to first electrode (refer to FIG. 3B). Accordingly, transfer from the electrode LH to electrode HOG (first and second electrodes) can be improved and the D range can also be improved. It is therefore possible to eliminate or alleviate both the demerit that a luminance of a high luminance object is lowered during image-capturing the high luminance object and the demerit that a sensitivity ratio is unbalanced during image-capturing a low luminance object. Further, since the number of addition pixels can be increased by increasing the D range, it becomes possible to increase a frame rate and a sensitivity. Specifications of an imager device such as a digital still camera can be extended greatly.

Furthermore, in the CCD solid state imager device according to the present embodiment, the ground potential is applied to the first electrode so that there is no problem of coupling while the horizontal transfer register is driven.

In the CCD solid state imager device according to the present embodiment, although a voltage is externally applied to the second electrode by way of example, the potential to be applied to the second electrode may be generated in the CCD solid state imager device.

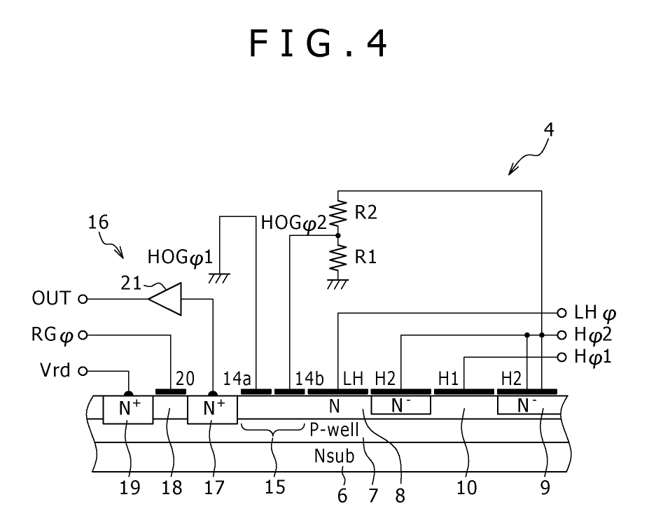

Specifically, as shown in FIG. 4, one ends of a first resistor R1 and a second resistor R2 are electrically connected to the second electrode, the other end of the first resistor R1 is electrically connected to the ground (earth) serving as a reference potential point, and the transfer clock Hφ1 applied to the electrode H2 is also applied to the other end of the second resistor R2. In this manner, the potential generated in the CCD solid state imager device is applied to the second electrode.

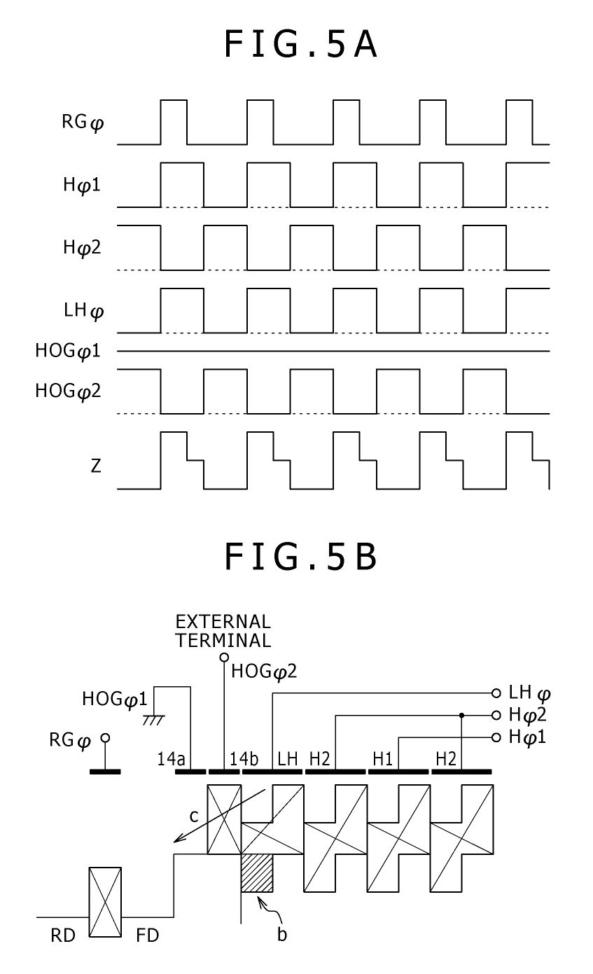

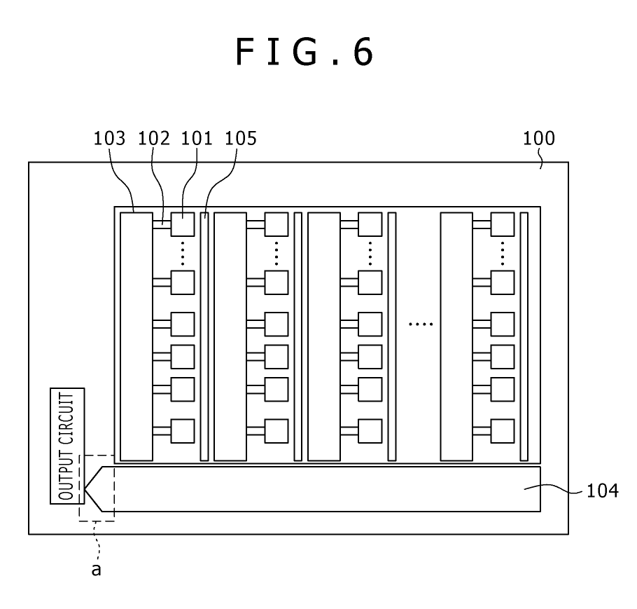

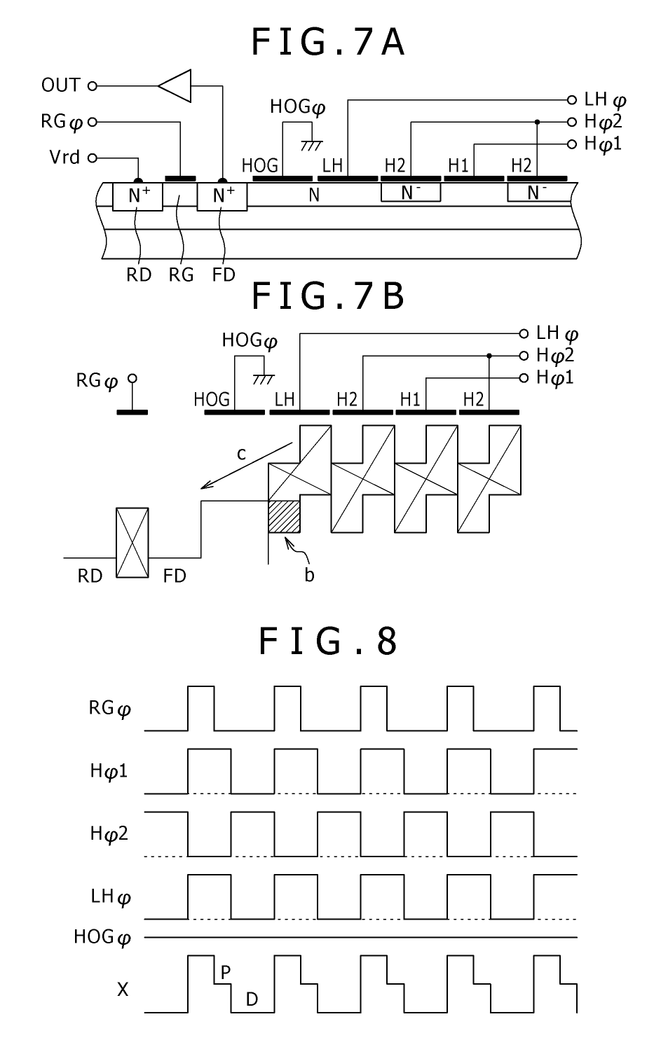

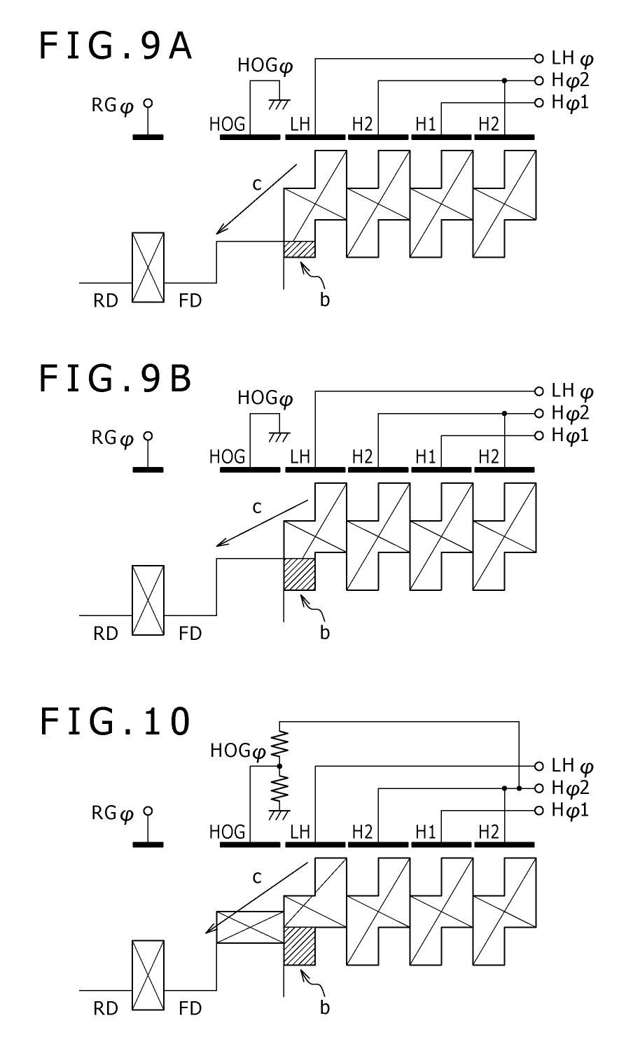

In the CCD solid state imager device constructed as shown in FIG. 2, a transfer clock indicated by a symbol Hφ1 in FIG. 5A is applied to the electrode H1, a transfer clock indicated by a symbol Hφ2 in FIG. 5A is applied to the electrode H2, a transfer clock indicated by a symbol LHφ in FIG. 5A is applied to the electrode LH at the last stage, a reset gate pulse indicated by a symbol RGφ in FIG. 5A is applied to the reset gate RG, a ground potential indicated by a symbol HOGφ1 in FIG. 5A is applied to the first electrode, and a transfer clock indicated by a symbol HOGφ2 in FIG. 5A is applied to the second electrode, to obtain an output signal of the CCD solid state imager device as indicated by a symbol Z in FIG. 5A. The transfer clock applied to the first electrode is almost synchronous with the transfer clocks applied to the electrodes H2.

In the CCD solid state imager device according to the present embodiment, as a transfer clock of the H level is applied to the second electrode, signal charges corresponding in amount to a potential difference between the second electrode and electrode LH can be accumulated so that the D range can be increased (refer to FIG. 5B). As a transfer clock of the L level is applied to the second electrode, a transfer electric field under the electrode LH, second electrode and first electrode can be made linearly so that transfer from the electrode LH to second electrode and from the second electrode to first electrode can be made smooth (refer to FIG. 5B). Namely, transfer from the electrode LH to electrode HOG (first and second electrodes) can be improved and the D range can also be improved. It is therefore possible to eliminate both the demerit that a luminance of a high luminance object is lowered during photographing the high luminance object and the demerit that a sensitivity ratio is unbalanced during photographing a low luminance object. Further, since the number of addition pixels can be increased by increasing the D range, it becomes possible to increase a frame rate and a sensitivity. Specifications of an imager device such as a digital still camera can be extended greatly.

Furthermore, in the CCD solid state imager device according to the present embodiment, the ground potential is applied to the first electrode so that there is no problem of coupling while the horizontal transfer register is driven.

The present application contains subject matter related to Japanese Patent Application JP 2006-157533 filed in the Japanese Patent Office on Jun. 6, 2006, the entire content of which being incorporated herein by reference.

In addition, the specific forms and structures of the various parts and the numerical values indicated in the embodiments and numerical embodiments described herein are merely examples for implementing the present invention, and the scope of the invention should in no way be limited thereby.

What is claimed is:

1. A charge transfer device comprising:
a charge transfer unit transferring signal charges; and
an electric charge-voltage conversion unit detecting signal charges transferred from a last stage of the charge transfer unit via an output gate unit,
wherein an electrode in a last stage of the charge transfer unit is divided into first and second electrodes,
a predetermined fixed potential is applied to the first electrode disposed on a side of the electric charge-voltage conversion unit, and
a transfer clock is applied to the second electrode disposed on a side opposite to the charge transfer unit.

2. The charge transfer device according to claim 1, wherein:
the second electrode is applied with a transfer clock having the same phase as a phase of a transfer clock applied to the charge transfer unit at a stage one stage before the last stage.

3. The charge transfer device according to claim 1, wherein:
the second electrode is applied with a transfer clock having a phase opposite to a phase of a transfer clock applied to the charge transfer unit at a stage one stage before the last stage.

4. A solid state imager device comprising:
an imager unit;
a charge transfer unit transferring signal charges transferred from the imager unit; and
an electric charge-voltage conversion unit detecting signal charges transferred from a last stage of the charge transfer unit via an output gate unit,
wherein an electrode in a last stage of the charge transfer unit is divided into first and second electrodes,
a predetermined fixed potential is applied to the first electrode disposed on a side of the electric charge-voltage conversion unit, and
a transfer clock is applied to the second electrode disposed on a side opposite to the charge transfer unit.

5. A charge transfer device comprising:
charge transfer means for transferring signal charges; and
charge detection means for detecting signal charges transferred from a last stage of the charge transfer means via an output gate means,
wherein an electrode applying a voltage to the output gate means is divided into first and second electrodes,
a predetermined fixed potential is applied to the first electrode disposed on a side of the charge detection means, and
a transfer clock is applied to the second electrode disposed on a side opposite to the charge transfer unit.
